(19) United States
(12) Patent Application Publication
(10) Pub. No.: US 2025/0172409 A1
(43) Pub. Date: May 29, 2025

(54) TEMPERATURE DEPENDENT CALIBRATION OF MOVEMENT DETECTION DEVICES

(71) Applicant: Magic Leap, Inc., Plantation, FL (US)

(72) Inventors: Cuthbert Martindale ALLEN, Miramar, FL (US); Michael Derek ABBOTT, Weston, FL (US); Igor LEVINSKY, Tel Aviv (IL); Jeffrey JOHNSON, Tampa, FL (US); Shimon GOLDSTEIN, Coral Springs, FL (US); Aaron Mark SCHUELKE, Coral Springs, FL (US)

(73) Assignee: Magic Leap, Inc., Plantation, FL (US)

(21) Appl. No.: 19/020,633

(22) Filed: Jan. 14, 2025

Related U.S. Application Data
(63) Continuation of application No. 18/161,616, filed on Jan. 30, 2023, now Pat. No. 12,247,846.
Application No. 18/161,616 is a division of application No. 17/262,991, filed on Jan. 25, 2021, now Pat. No. 11,598,651.
(60) Provisional application No. 62/702,870, filed on Jul. 24, 2018.

(51) Int. Cl. G01C 25/00; B81B 7/02

(52) U.S. Cl. CPC G01C 25/005; B81B 7/02; B81B 2201/0235; B81B 2201/0242

(57) ABSTRACT

An electronics system has a board with a thermal interface having an exposed surface. A thermoelectric device is placed against the thermal interface to heat the board. Heat transfers through the board from a first region where the thermal interface is located to a second region where an electronics device is mounted. The electronics device has a temperature sensor that detects the temperature of the electronics device. The temperature of the electronics device is used to calibrate an accelerometer and a gyroscope in the electronics device. Calibration data includes a temperature and a corresponding acceleration offset and a corresponding angle offset. A field computer simultaneously senses a temperature, an acceleration and an angle from the temperature sensor, accelerometer and gyroscope and adjusts the measured data with the offset data at the same temperature. The field computer provides corrected data to a controlled system.

### CROSS-REFERENCE TO RELATED APPLICATIONS

This application is a continuation of U.S. patent application Ser. No. 18/161,616, filed on Jan. 30, 2023, which is a division of U.S. patent application Ser. No. 17/262,991, filed on Jan. 25, 2021 now U.S. Pat. No. 11,598,651, which is a National Phase of International Application No: PCT/US2019/043099, filed on Jul. 23, 2019, which claims priority from U.S. Provisional Patent Application No. 62/702,870, filed on Jul. 24, 2018, all of which are incorporated herein by reference in their entirety.

### BACKGROUND OF THE INVENTION

### 1). Field of the Invention

This invention relates generally to an electronics system, a method of constructing an electronics system and a method of operating an electronics device, and more specifically to calibration of movement detection devices.

### 2). Discussion of Related Art

Electronics devices such as semiconductor chips frequently include movement detection devices such as accelerometers and gyroscopes. An accelerometer can detect acceleration of the electronics device in a specified direction and a gyroscope can detect a change in angle of the electronics device. Such measurement devices are usually manufactured using microelectromechanical systems (MEMS) technology.

### SUMMARY OF THE INVENTION

The invention provides an electronics system including a board. The board may include a structural material, a thermal conduit on the structural material, the thermal conduit having a thermal conductivity that is higher than a thermal conductivity of the structural material and having a first region, a second region, and a connecting portion connecting the first region to the second region, a thermal interface on the structural material, the thermal interface having a thermal heat transfer capacity that is higher than the thermal heat transfer capacity of the structural material and being attached to the first region of the thermal conduit and an electronics device mounted to the board at the second region of the thermal conduit, the thermal conduit forming a thermal path between the surface of the thermal interface and the electronics device.

The invention also provides a method of constructing an electronics system including constructing a board that may include forming a thermal conduit on the structural material, the thermal conduit having a thermal heat transfer capacity that is higher than a thermal heat transfer capacity of the structural material and having a first region, a second region, and a connecting portion connecting the first region to the second region, forming a thermal interface on the structural material, the thermal interface having a thermal heat transfer capacity conductivity that is higher than the thermal heat transfer capacity of the structural material and being attached to the first region of the thermal conduit and mounting an electronics device to the board at the second region of the thermal conduit, the thermal conduit forming a thermal path between the surface of the thermal interface and the electronics device.

The invention further provides a method of operating an electronics device including operating an electronics device mounted to a board, locating a thermal device adjacent a thermal interface of the board formed on a structural material of the board and transferring heat between the thermal device and the electronics device through a thermal conduit on the structural material, the thermal conduit having a thermal heat transfer capacity that is higher than a thermal heat transfer capacity of the structural material and having a first region attached to the thermal interface, a second region at the electronics device, and a connecting portion connecting the first region to the second region.

### BRIEF DESCRIPTION OF THE DRAWINGS

The invention is described by way of examples with reference to the accompanying drawings, wherein:

FIG. 1 is a top view in a first plane of an electronics system according to an embodiment of the invention;

FIG. 2 is a cross-sectional side view of the electronics system in a second plane on 2-2 in FIG. 1;

FIG. 3 is a cross-sectional side view of the electronics system in a third plane on 3-3 in FIG. 1;

FIG. 4 is a side view similar to FIG. 1 and further illustrates an electronics device forming part of the electronics system;

FIG. 5 is cross-sectional side view on 5-5 in FIG. 4 showing with to a close-up detailed view of the electronics device;

FIG. 6 is a cross-sectional side view of the electronics system further illustrating a calibration station;

FIG. 7 is a cross-sectional side view of the electronics system further illustrating the use of the calibration station to heat and calibrate the electronics device of the electronics system;

FIG. 8 is cross-sectional side view of the electronics system, further showing a field computer and a controlled system that uses calibration data; and

FIG. 9 is a cross-sectional side view of an electronics system according to another embodiment of the invention.

### DETAILED DESCRIPTION OF THE INVENTION

Output readings from movement detection devices, such as accelerometers and gyroscopes, can be affected by changes in temperature of the devices, thereby introducing temperature-dependent error in the output measurements. For example, an accelerometer at rest should provide an output measurement corresponding to gravitational acceleration; however when the accelerometer is subjected to different temperatures, the output measurement will be different due to error associated with the accelerometer being at a higher temperature. Because the output should not change while the accelerometer is at rest, that is, acceleration is still only gravity regardless of the temperature, it is possible to isolate the output measurement error associated with temperature by finding the difference (or “offset”) between the erroneous measurement and the known baseline measurement (gravity in the case of an accelerometer). By conducting this measurement comparison at multiple temperatures, many data points are collected and an offset profile over a range of temperatures can be obtained. The collection of data associating temperatures with specific offset readings can be compiled for each movement detection device during the calibration process. The data can be stored as calibration data in a table for look up or extrapolation, or can be used to define a best fit function. The calibration data can be accessed by a virtual reality, augmented reality, or mixed reality system to obtain an adjusted measurement from a movement detection device given the temperature of the movement detection device and its initial “raw” measurement.

A calibration system and process that improves calibration accuracy is described herein. Known methods of calibrating movement detection devices involve contacting the movement detection device with a thermal probe to introduce heat by conduction or require actively blowing air across the movement detection device to adjust its temperature by convection. Both of these methods can cause the device to move so that a measurement taken from the device during calibration will include an error associated with temperature and an error associated with movement introduced by the measurement method. Because it is not possible to know how much movement is introduced by the measurement method, it is not possible to isolate the error associated with temperature. As a result, the error cannot be accurately removed from the raw output measurement of the device. In virtual, augmented, and mixed reality systems, the accuracy of a measurement taken by a device is critical for determining where to display virtual content to a user with respect to movement between the user and the real or virtual environment. Thus, there exists a need for a highly accurate calibration system and method in a virtual, augmented, or mixed reality device.

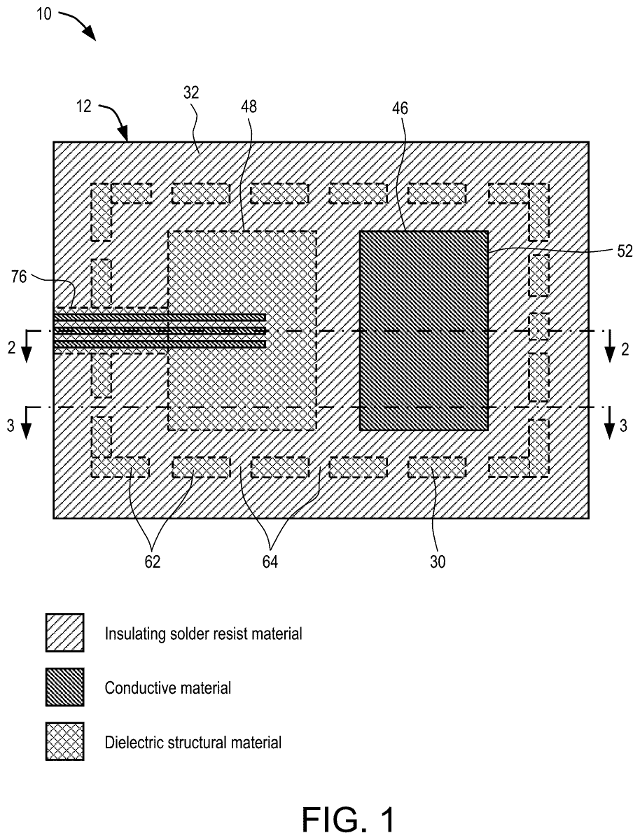

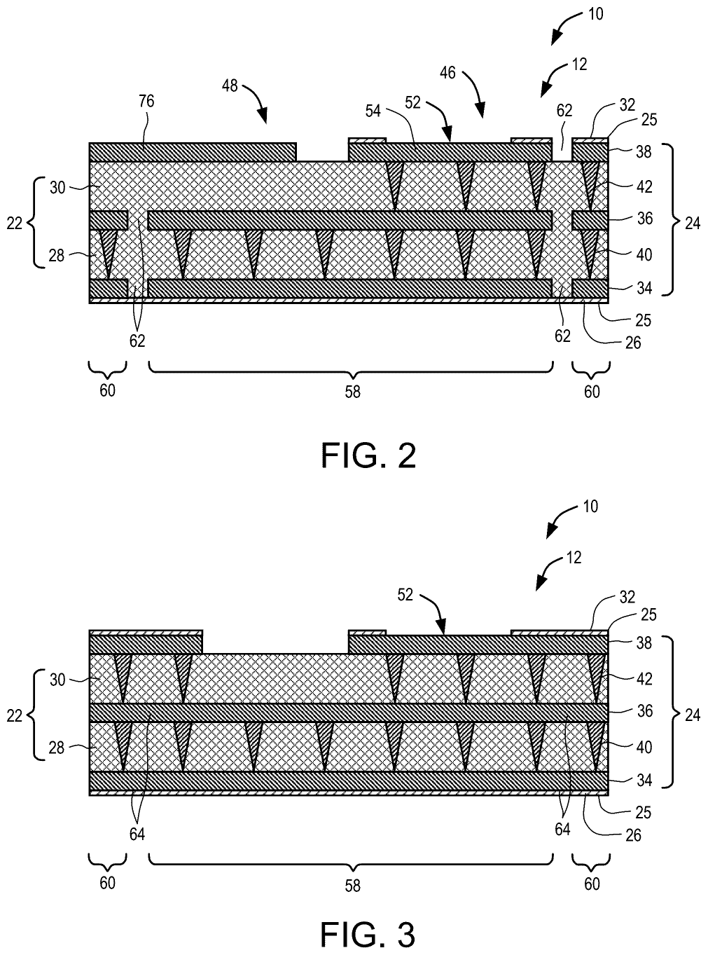

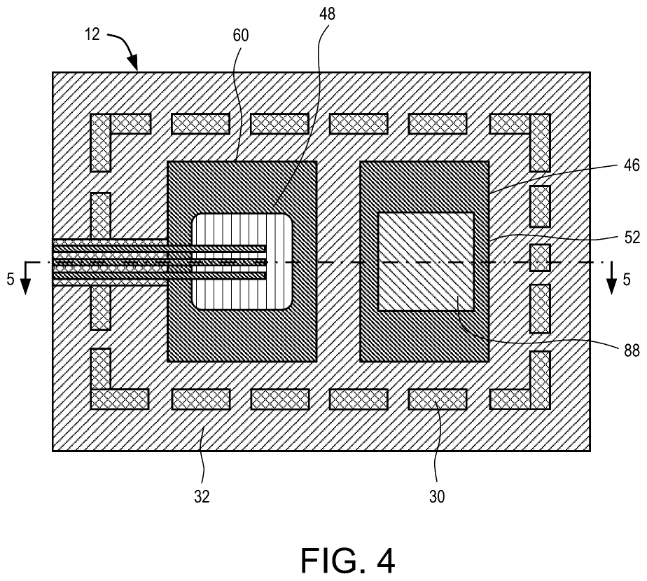

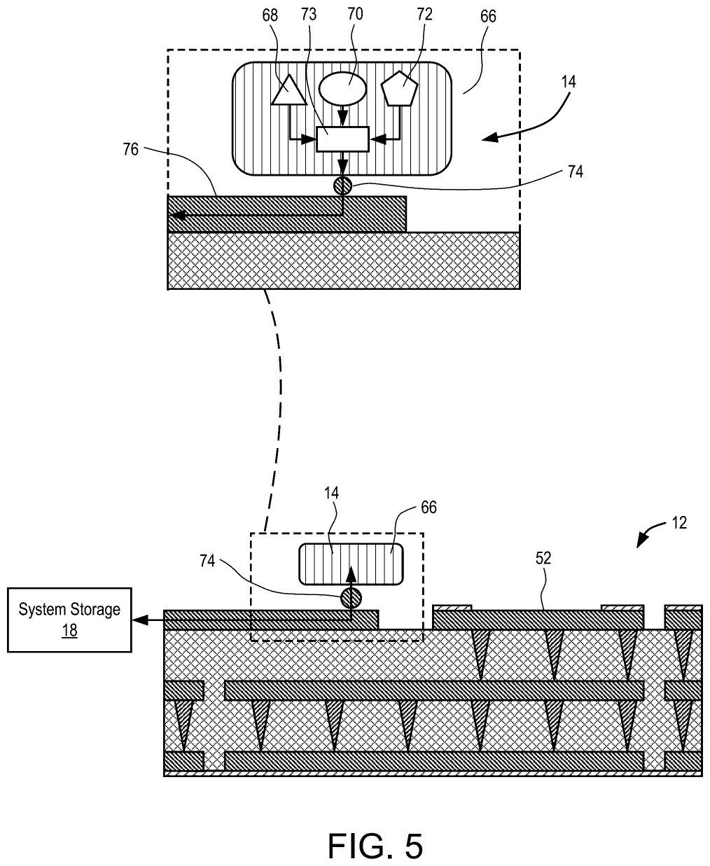

FIGS. 1, 2 and 3 illustrate an electronics system 10, according to an embodiment of the disclosure. FIG. 1 is a top view of an example configuration of a board 12 in the electronics system 10. FIG. 2 is a cross-sectional side view on 2-2 in FIG. 1. FIG. 3 is a cross-sectional side view on 3-3 in FIG. 1. The electronics system 10 includes a board 12 made up of multiple layers of different materials. The layers and various features disposed therein provide particular functions during calibration and use of an electronics device 14 (discussed with respect to FIGS. 4 and 5), such as a sensor or sensor suite, connected to the board 12.

The board 12 is constructed from structural material 22, such as FR4 dielectric, and a thermally and electrically conductive material, such as metal components 24. Metal components 24 may include a copper material. The metal of the metal components 24 is more thermally conductive, and therefore has a higher thermal heat transfer capacity, than the structural material 22. The metal of the metal components 24 is electrically conductive and the structural material 22 is electrically insulating.

Multiple layers of structural material 22 can be included in the board 12. As shown in the example of FIGS. 2 and 3, two structural layers 28 and 30 can be provided. The metal components 24 are disposed between the layers of structural material 22. For example, the metal components 24 can include first, second and third metal layers 34, 36 and 38 separated by the first and second structural layers 28 and 30. The board 12 further includes top and bottom insulating layers 32 and 26 that cover the first and third metal layers 34 and 38. The top and bottom insulating layers 32 and 26 can include an electrically insulating solder resist material 25.

The metal components 24 also include first and second sets of vias 40 and 42, respectively. The first set of vias 40 connects portions of the first metal layer 34 to portions of the second metal layer 36. The second set of vias 42 connects portions of the second metal layer 36 to portions of the third metal layer 38. The metal layers 34, 36 and 38 are thereby electrically and thermally connected to one another. The metal layers 34, 36 and 38 together with the first and second sets of vias 40 and 42 form a thermal conduit of thermally conductive material that connect a first region 46 of the thermal conduit to a second region 48 of the thermal conduit.

Portions of the third metal layer 38 are isolated as metal lines 76 to function as traces for electrical signals. These metal lines 76 can be isolated from each other and from other metal components 24 such that each line is surrounded by non-conductive material, such as dielectric structural material 22 and insulating solder resist material 25. One of skill in the art will appreciate that more or fewer than three metal lines 76 may be provided depending on the design of the electronic device 14 that is mounted to the board 12 at the second region 48. The metal lines 76 may be disposed in one or more of the metal layers in the board 12. Additionally, while the lines 76 are shown as exposed parts of the metal component 24, portions of the metal lines 76 can also be coated with the insulating solder resist material 25.

The metal components 24 further include a thermal interface 52. The thermal interface 52 is an area of the third metal layer 38 at the first region 46 that has been exposed by removing a portion of the top insulating layer 32. The thermal interface 52 is an upper surface 54 of third metal layer 38 that is exposed and is configured to contact part of an electronic device calibration station 80. The upper surface 54 forms only a portion of an upper surface of the board 12, with the remainder of the upper surface consisting of an upper surface of the structural layer 30 and insulating solder resist layer 32.

Referring to FIGS. 1 and 2 in combination, the first, second, and third metal layers 34, 36, 38 have an inner portion 58 and an outer portion 60. The structural material 22 forms a plurality of barriers 62 that distinguish the inner portion 58 from the outer portion 60. The barriers 62 act as thermal barriers to prevent heat from conducting from the inner portion 58 to the outer portion 60 of the second metal layer 36, or at least substantially slow the transfer of heat so that the outer portion 60 is kept cooler than the inner portion 58. Additional electronic components can be connected to the board 12. Such components can be connected to the board 12 at the outer portion 60 to keep the components from experiencing high heat during the calibration process.

Referring to FIGS. 1 and 3 in combination, it can be seen that the first, second, and third metal layers 34, 36, 38 also have connecting portions 64 that connect the inner portion 58 to the outer portion 60. The connecting portions 64 ensure that the metal layers are electrically grounded such that there is an equal reference voltage between the inner portion 58 and the outer portion 60.

Referring to FIGS. 1 and 2 in combination, it can be seen that similar thermal barriers 62 are formed at one or more positions within the first, second and third metal layers 34, 36 and 38 (FIG. 1) and that each metal layer has respective portions 64 connecting inner and outer regions thereof. The barriers 62 prevent, or at least slow heat transfer from the inner portion 58 to the outer portion 60 to protect other components attached to the board 12 from experiencing high temperatures during the calibration of electronics device 14.

Referring to FIGS. 4 and 5, the electronics system 10 further includes an electronics device 14 and a system storage 18. The electronics device 14 is mounted to an upper surface of the board 12 through connections 74. The electronics device 14 and the thermal interface 52 are within the barriers 62 that define the inner portion 58. The electronics device 14 is mounted above the second region 48 of the thermal conduit described above.

The electronics system 10 further includes a board interface 16 that is attached to the board 12 and connected to the measurement devices in the electronics device 14. The electronics device 14 includes a structural body 66 and a number measurement devices in the structural body 66. The measurement devices include a temperature sensor 68 and two movement detection device in the form of an accelerometer 70 and a gyroscope 72. Although two movement detection devices are used for purposes of this embodiment, it may be possible to implement aspects of the invention using only one measurement device. It may for example be possible to calibrate an electronics device having only a gyroscope or only an accelerometer. The structural body 66 may, for example, be a silicon or other semiconductor structural body that may be packaged using conventional packaging technologies. The temperature sensor 68, accelerometer 70 and gyroscope 72 are connected through connectors 74 on an upper surface of the board 12 and metal lines 76 in the board 12 to the board interface 16. Data traces from the temperature sensor 68, accelerometer 70, and gyroscope 72 are routed to a microprocessor 73 in the structural body 66 which serves as an input/output interface for the measurement devices. The system storage 18 serves to store calibration data received from the calibration station 80 that is associated with the accelerometer 70 and gyroscope 72. The system storage 18 may, for example, include a solid-state memory. The system storage 18 is shown near the electronics device 14, however, the system storage may be a remote storage, located on a cloud-based storage or on another area of the electronics device such that it is not in contact with the board 12. One of skill in the art will appreciate that the system storage 18 may be located anywhere that is in communication with electronics device 14 to allow for data transfer between electronics device 14 and system storage 18. The system storage 18 includes no calibration data immediately after the electronics system 10 has been assembled (that is, prior to undergoing calibration) but is uniquely associated with the electronics device 14 by enabling data to transfer between the electronics device 14 and the system storage 18.

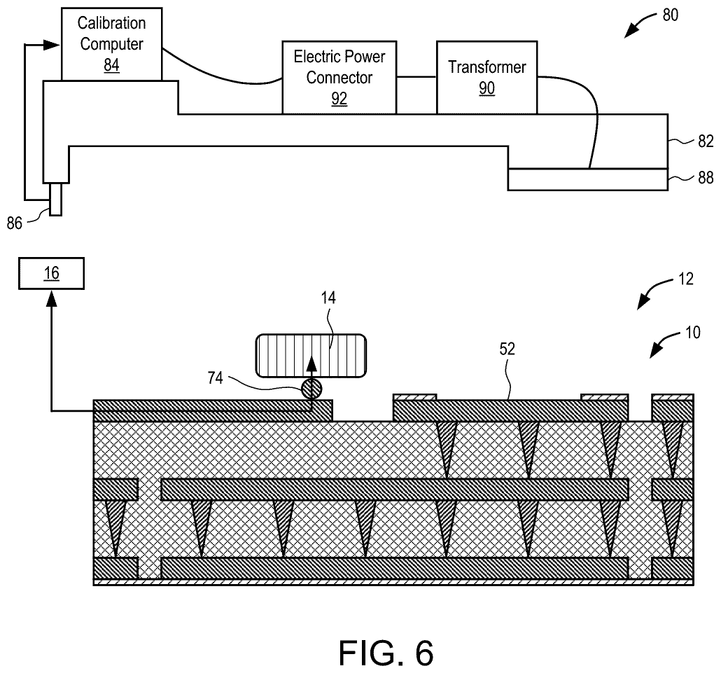

FIG. 6 further illustrates a calibration station 80 that is used to calibrate the accelerometer 70 and the gyroscope 72. The calibration station 80 includes a frame 82, a calibration computer 84, a calibration computer interface 86, a thermoelectric device 88, a transformer 90 and an electric power connector 92. The components of the calibration station 80 are mounted in a stationary position to one another via the frame 82. A spacing between the calibration computer interface 86 and the thermoelectric device 88 is the same as a spacing between the board interface 16 and the thermal interface 52. The calibration computer 84 is connected to the calibration computer interface 86 so that signals can transmit between the calibration computer 84 and the calibration computer interface 86. Information from the microprocessor 73 can be accessed by the calibration station 80. The calibration computer 84 is connected to the electric power connector 92 so that power can be provided through the electric power connector 92 to the calibration computer 84. The thermoelectric device 88 is connected through the transformer 90 to the electric power connector 92. The power can be provided by the electric power connector 92 through the transformer 90 to the thermoelectric device 88. The transformer 90 reduces the voltage provided by the electric power connector 92 before providing power to the thermoelectric device 88. The thermoelectric device 88 is preferably a reversible heat pump, such as a thermoelectric cooler, capable of providing heat into the board 12 or drawing heat out of the board 12. The flexibility to achieve a wide range of temperatures on the board 12, and thus at the electronics device 14, can improve calibration accuracy of the electronic device 14.

In use, the electronics system 10 is brought into contact with portions of the calibration station 80. When the electronics system 10 and the calibration station 80 move relatively towards one another, the calibration computer interface 86 connects to the board interface 16 and can begin receiving data from the electronics device 14 at the same time that the thermoelectric device 88 comes into contact with the thermal interface 52. In the embodiment described, the calibration computer interface 86 and the board interface 16 are wired interfaces that come into contact with one another to create a communication link and are releasable from one another to break the communication link. Data is received through a wired communication between the electronics system 10 and the calibration station 80. In another embodiment, the calibration station 80 and the board may include wireless interfaces that create a wireless link for data transfer and the wireless link sis then broken.

Electric power is provided through the electric power connector 92 to the calibration computer 84, which powers the calibration computer 84. Electric power is also provided through the electric power connector 92 and the transformer 90 to the thermoelectric device 88.

The entire electronics system 10 can begin calibration initially at room temperature, e.g. approximately 21° C. The temperature sensor 68 (FIG. 5) provides an output of the temperature to the calibration computer 84. The accelerometer 70 and the gyroscope 72 simultaneously provide outputs to the calibration computer 84 that are associated with the output temperature from the temperature sensor 68. Baseline outputs for the accelerometer and the gyroscope are either known because the device is at rest or are established at a reference temperature, such as at room temperature. These baseline outputs are used later in the calibration process to isolate errors in measurements (“offsets”) that are associated with temperature changes of the sensors.

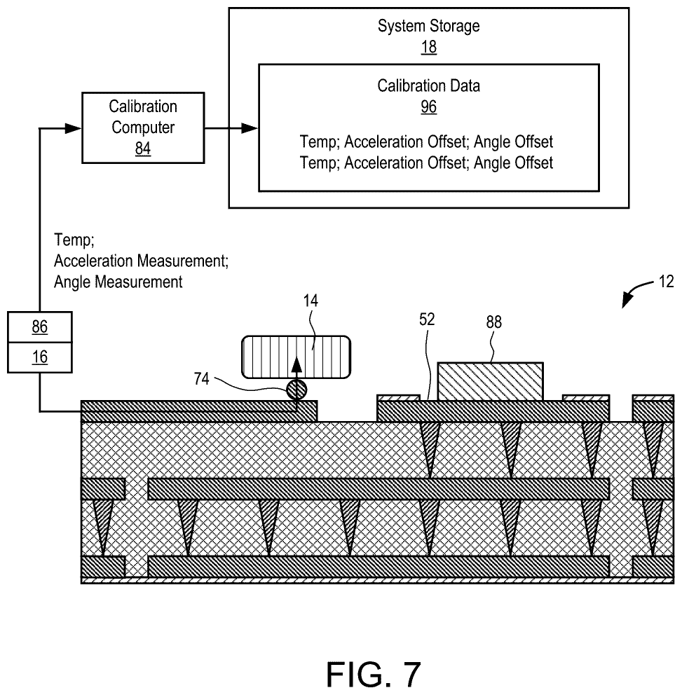

FIG. 7 illustrates that the calibration computer 84 is connected to the system storage 18 and records calibration data 96 in the system storage 18 as the calibration offsets are calculated. A first entry in a table of the calibration data 96 includes the initial temperature (in this example, 21° C.), an acceleration offset (calculated by finding the difference between the acceleration measurement at temperature and the known acceleration), and an angle offset (calculated by finding the difference between the gyroscope measurement at temperature and the known positional information) that are calculated for a given temperature sensor measurement using inputs from accelerometer 70 and gyroscope 72, respectively.

The thermoelectric device 88 has an upper surface that is at a lower temperature than room temperature and a lower surface that is at a higher temperature than room temperature. Heat transfers from the high temperature, lower surface of the thermoelectric device 88 through the upper surface 54 of the thermal interface 52 into the thermal interface 52. The heat transfer is primarily by way of conduction. The heat then conducts through the third metal layer 38 and first and second sets of vias 40 and 42 to the first and second metal layers 34 and 36. The heat then conducts through the first, second and third metal layers 34, 36 and 38 from the first region 46 nearest the heat source outward toward the second region 48. The barriers 62 prevent or at least substantially retard transfer of heat from the inner portion 58 to the outer portion 60.

Heating of the second region 48 causes its temperature to increase. Conduction of heat through the metal layers 34, 36, 38 and the thermal vias 40, 42 happens rapidly while significantly slower conduction of heat occurs in the structural material layers 28, 30. Conduction through top metal layer 38 evenly distributes heat underneath electronics device 14 in the second region 48. The increased temperature of the second region 48 causes heat transfer through conduction by connection 74 and through passive convection of air surrounding the electronics device 14. This method of heating electronics device 14 closely mimics the field conditions that the electronic device 14 will experience. The temperature sensor 68 continues to detect the temperature of the electronics device 14. The calibration computer 84 samples the temperature of the temperature sensor 68 on a predetermined interval, e.g. every five seconds, or more frequently for improved accuracy. The calibration computer 84 also samples outputs from the accelerometer 70 and the gyroscope 72 at the same time that the calibration computer 84 samples a temperature from the temperature sensor 68. The calibration computer 84 then calculates and stores each temperature and each acceleration offset and each angle offset with the calibration data 96. As described herein previously, each temperature is associated with an acceleration offset and an angle offset component within the measurement readings of the accelerometer and gyroscope, respectively. An offset profile can be obtained by measuring outputs of each sensor across a range of temperatures, each time subtracting the known value that the sensor should measure from the actual measurement to calculate error. Each temperature thus has a different acceleration offset and angle offset associated therewith, even though the accelerometer 70 and gyroscope 72 remain stationary from one measurement to the next. In some embodiments, multiple measurements are obtained at each temperature and an average offset is calculated for improved accuracy.

When sufficient data is collected, the calibration station 80 is removed from contact with the board 12. The calibration computer interface 86 writes the collected calibration data to the system storage 18 and disconnects from the board interface 16. The thermoelectric device 88 disengages from the thermal interface 52. Heat convects and conducts from the electronics device 14 until the entire electronics device 14 returns to room temperature.

The calibration system and process described above do not require physical contact between the calibration station and the electronics device 14 and furthermore do not require forced convection across electronics device 14. Rather, the electronics device 14 is heated by way of conduction through a permanent connection (connectors 74 and metal lines 76) to the board 12 and by way of passive convection without the need for additional probe contact with or forced air blowing over the electronics device 14. The electronics device 14 can thus be calibrated against temperature without disturbing the accelerometer 70 or the gyroscope 72. This system and process allows for a more accurate offset calibration while mimicking real field conditions of the sensors on board electronics device 14.

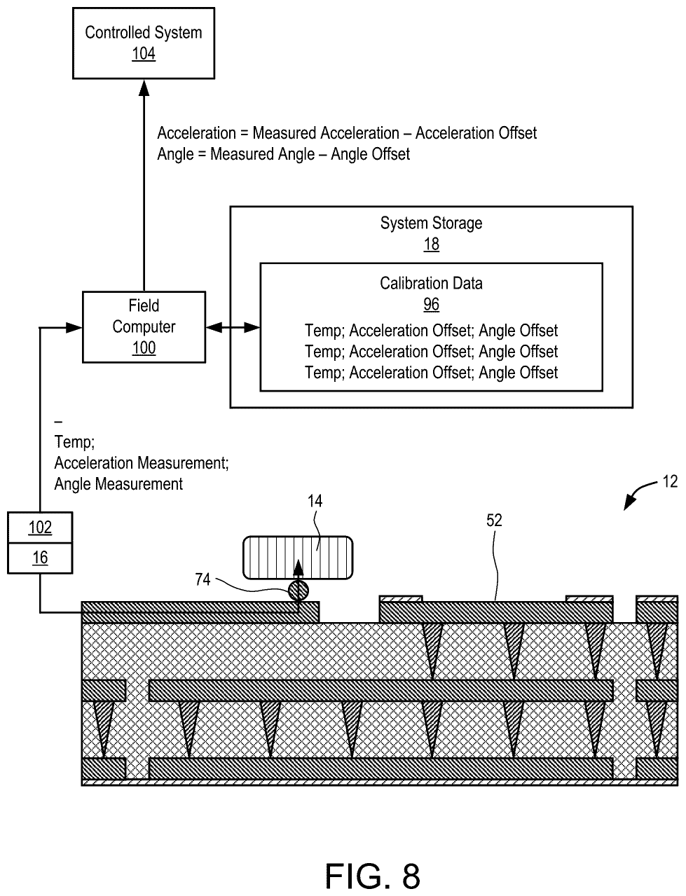

FIG. 8 illustrates the electronics system in conjunction with a field computer 100, a field computer interface 102 and a controlled system 104. The controlled system 104 may be, for example, a virtual reality, augmented reality, or mixed reality device. The field computer 100 is connected to the field computer interface 102. The controlled system 104 is connected to the field computer 100. The field computer 100 may, for example, be a computer that processes movement data of an augmented reality viewing system and the controlled system 104 may be a vision processing system of the viewing device. The field computer 100 is connected to the system storage 18 and has access to the calibration data 96.

In use, the electronics system 10 is moved, e.g. in linear directions or rotational directions. The accelerometer 70 and the gyroscope 72 detect such movement of the electronics system 10. The field computer 100 senses signals received from the temperature sensor 68, accelerometer 70 and gyroscope 72. The field computer 100 uses the temperature detected by the temperature sensor 68 to find a corresponding temperature in the calibration data 96. The calibration data 96 may include the table with data as hereinbefore described or may include a formula, such as a linear regression, representative of the calibration data. The field computer 100 retrieves the acceleration offset and the angle offset in the calibration data 96 corresponding to the temperature measured by the temperature sensor 68. The field computer 100 then adjusts the acceleration detected by the accelerometer 70 by the acceleration offset (acceleration=measured acceleration-acceleration offset). The field computer 100 also adjusts an angle measured by the gyroscope 72 by the angle offset corresponding to the temperature (adjusted angle=measured angle-angle offset). The field computer 100 then provides the adjusted acceleration and the adjusted angle to the controlled system 104. The controlled system 104 utilizes the adjusted acceleration and the adjusted angle in one or more formulas. By way of example, the controlled system 104 adjusts placement of a rendered image in an augmented reality or mixed reality viewing device according to a placement formula that uses the adjusted acceleration and the adjusted angle received from the field computer 100.

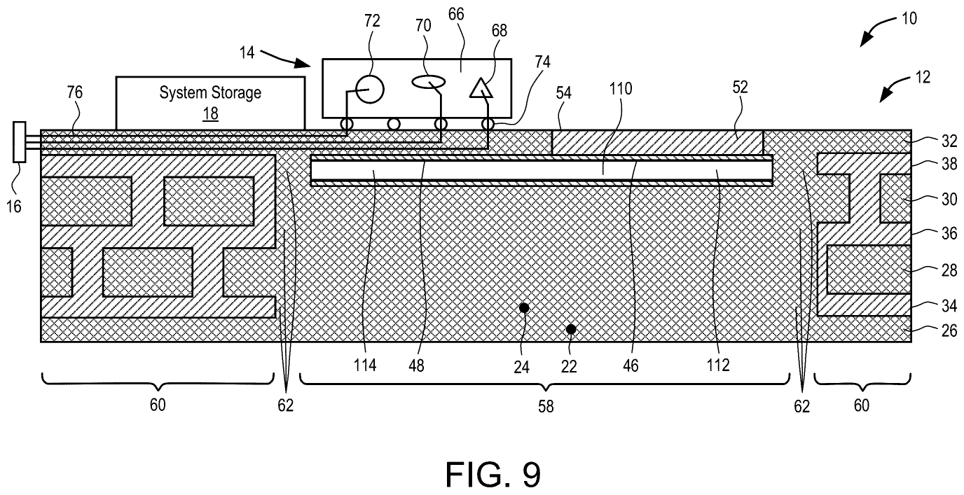

FIG. 9 illustrates an alternate embodiment wherein a thermal conduit is provided by any known heat spreader that can be built into a chip. In some embodiments, the heat spreader can be a heat pipe 110. The heat pipe 110 has an evaporator end 112 and a condenser end 114. The evaporator end 112 is located against or in close proximity to the thermal interface 52 and the condenser end 114 is located in close proximity to the electronics device 14. In use, the thermal interface 52 heats a liquid in the heat pipe 110 and evaporates the liquid. The resultant vapor flows from the evaporator end 112 to the condenser end 114 and condenses. The resulting condensed liquid then flows through a wicking system from the condenser end 114 back to the evaporator end 112.

FIGS. 1 to 8 illustrate one type of thermal conduit consisting of a thermally conductive metal. The design in FIGS. 1 to 8 is relatively inexpensive to manufacture. FIG. 9 illustrates a different type of thermal conduit in the form of a heat pipe. A heat pipe may transfer more heat, through flow, than thermally conductive metal but may be more expensive to manufacture. The thermal conduit provided by the thermally conductive metal in FIGS. 1 to 8 and the thermal conduit provided by the heat pipe in FIG. 9 both have a thermal heat transfer capacity that is higher than a thermal heat transfer capacity of the structural material 22 of the board 12 and both form a thermal path between the surface of the thermal interface 52 and the electronics device 14.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. An electronics system comprising:
a board that includes:
a structural material;
a thermal conduit on the structural material, the thermal conduit having a thermal conductivity that is higher than a thermal conductivity of the structural material and having a first region, a second region, and a connecting portion connecting the first region to the second region;
a thermal interface on the structural material, the thermal interface having a thermal heat transfer capacity that is higher than the thermal heat transfer capacity of the structural material and being attached to the first region of the thermal conduit; and
an electronics device mounted to the board at the second region of the thermal conduit, the thermal conduit forming a thermal path between the surface of the thermal interface and the electronics device,
wherein the thermal conduit includes: a metal conductor made of at least two metal layers, the at least two metal layers being separated by a layer of the structural material and partially located below the electronics device; and a plurality of metal vias connecting the layers to one another, at least one of the plurality of metal vias located below the electronics device.

2. The electronics system of claim 1, wherein the metal conductor is made of a metal that is more thermally conductive than the structural material.

3. The electronics system of claim 1, wherein the board has at least one metal layer having an inner portion and an outer portion and the structural material forms a barrier between the inner portion and the outer portion, the inner portion forming the thermal conduit, and the thermal interface and the electronics device being located over the inner portion.

4. The electronics system of claim 3, wherein the metal layer is more electrically conductive than the structural material.

5. The electronics system of claim 3, wherein the structural material forms a plurality of barriers between the inner portion and the outer portion, wherein the barriers are alternated with portions of the metal layer that connect the inner portion to one another.

6. The electronics system of claim, 1, further comprising:
a movement detection device in the electronics device;
a system storage; and
calibration data on the system storage, the calibration data including
a first temperature of the movement detection device;
a first output from the movement detection device recorded against the first temperature; and
a second temperature of the movement detection device that is different than the first temperature; and
a second output from the movement detection device recorded against the second temperature.

7. The electronics system of claim 6, wherein the movement detection device is an accelerometer.

8. The electronics system of claim 6, wherein the movement detection device is a gyroscope.

9. The electronics system of claim 6, further comprising:
a temperature detector in the electronics device.

10. The electronics system of claim 9, further comprising:
a field computer;
an interface connecting the field computer to the movement detection device and the temperature detector; and
a controlled system connected to the field computer.

11. A method of constructing an electronics system comprising:
constructing a board including:
forming a thermal conduit on the structural material, the thermal conduit having a thermal heat transfer capacity that is higher than a thermal heat transfer capacity of the structural material and having a first region, a second region, and a connecting portion connecting the first region to the second region;
forming a thermal interface on the structural material, the thermal interface having a thermal heat transfer capacity conductivity that is higher than the thermal heat transfer capacity of the structural material and being attached to the first region of the thermal conduit; and
mounting an electronics device to the board at the second region of the thermal conduit, the thermal conduit forming a thermal path between the surface of the thermal interface and the electronics device,
wherein the thermal conduit includes: a metal conductor made of at least two metal layers, the at least two metal layers being separated by a layer of the structural material and partially located below the electronics device; and a plurality of metal vias connecting the layers to one another, at least one of the plurality of metal vias located below the electronics device.

12. A method of operating an electronics device comprising:
operating an electronics device mounted to a board;
locating a thermal device adjacent a thermal interface of the board formed on a structural material of the board; and
transferring heat between the thermal device and the electronics device through a thermal conduit on the structural material, the thermal conduit having a thermal heat transfer capacity that is higher than a thermal heat transfer capacity of the structural material and having a first region attached to the thermal interface, a second region at the electronics device, and a connecting portion connecting the first region to the second region,
wherein the thermal conduit includes: a metal conductor made of at least two metal layers, the at least two metal layers being separated by a layer of the structural material and partially located below the electronics device; and a plurality of metal vias connecting the layers to one another, at least one of the plurality of metal vias located below the electronics device.

13. The method of claim 12, further comprising:
calibrating a movement detection device in the electronics device that detects movement while transferring the heat, the calibration of the device including:
detecting a first temperature of the movement detection device;
detecting a first output from the movement detection device;
calculating a first offset based on the first output and a first baseline output;
recording the first temperature and the first offset;
changing a temperature of the movement detection device from the first temperature to a second temperature;
detecting the second temperature of the movement detection device;
detecting a second output from the movement detection device;
calculating a second offset based on the second output and a second baseline output; and
recording the second temperature and the second offset.

14. The method of claim 13, further comprising:
removing the thermal device from the thermal interface after the calibration of the movement detection device.
